(19) United States
(12) Patent Application Publication
(10) Pub. No.: US 2026/0343787 A1
(43) Pub. Date: Oct. 29, 2026

(54) MULTI-SECTION SLIDE RAIL DEVICE

(71) Applicant: FOSITEK CORPORATION, New Taipei City (TW)

(72) Inventors: Shih-Yuan HSU, New Taipei City (TW); Jhih-Cin YANG, New Taipei City (TW)

(73) Assignee: FOSITEK CORPORATION, New Taipei City (TW)

(21) Appl. No.: 19/263,243

(22) Filed: Jul. 8, 2025

(30) Foreign Application Priority Data
Apr. 29, 2025 (TW) 114116167

(51) Int. Cl. H05K 7/18; H05K 7/14

(52) U.S. Cl. CPC H05K 7/183; H05K 7/1488

(57) ABSTRACT

A multi-section slide rail device includes a first rail section, a second rail section and a bracing member. The first rail section has a first upright wall and two first lateral walls which respectively extend from upper and lower side edges of the first upright wall in a transverse direction. The second rail section is disposed on and slidable relative to the first rail section, and has a second upright wall and two second lateral walls which respectively extend from upper and lower side edges of the second upright wall. The bracing member is disposed on the second rail section and is in abutting engagement with the second lateral walls in an upright direction.

### CROSS-REFERENCE TO RELATED APPLICATION

This application claims priority to Taiwanese Patent Application No. 114116167, filed on Apr. 29, 2025, the entire disclosure of which is incorporated by reference herein.

### FIELD

The disclosure relates to a slide rail device, and more particularly to a multi-section slide rail device for a server rack.

### BACKGROUND

A conventional three-section slide rail device is disposed on a server rack for mounting a server case thereon. The slide rail device includes an outer rail section, a middle rail section disposed on and slidable relative to the outer rail section, and an inner rail section disposed on and slidable relative to the middle rail section for the server case to be mounted thereon. When the server case needs to be pulled out from the slide rail device for maintenance, the slide rail device is moved to an extended state where the inner rail section is extended relative to the middle rail section and the middle rail section is extended relative to the outer rail section. In this state, a torque is generated by the server case and is applied to the middle rail section and the inner rail section, which may cause bending, deformation or even breaking of the middle and inner rail sections after a prolonged period. A plate-like reinforcing structure is disposed on the rail sections to increase the load capacity of the middle and inner rail sections. However, there is no bracing members to support the lateral walls of the middle and inner rail sections, so the load on the rail sections is not dispersed efficiently.

### SUMMARY

Therefore, an object of the disclosure is to provide a multi-section slide rail device that can alleviate at least one of the drawbacks of the prior art.

According to the disclosure, the multi-section slide rail device includes a first rail section, a second rail section and a bracing member. The first rail section has a first upright wall which extends in a lengthwise direction and has a first upper side edge and a first lower side edge, and two first lateral walls which respectively extend from the first upper side edge and the first lower side edge in a transverse direction that is transverse to the lengthwise direction. The second rail section is disposed on and slidable relative to the first rail section along the lengthwise direction, and has a second upright wall which extends in the lengthwise direction and has a second upper side edge and a second lower side edge, and two second lateral walls which respectively extend from the second upper side edge and the second lower side edge in the transverse direction. The bracing member is disposed on the second rail section and is in abutting engagement with the second lateral walls in an upright direction that is transverse to both of the lengthwise direction and the transverse direction.

With the bracing member disposed on the second rail section and in abutting engagement with the second lateral walls, the structural strength of the second rail section is increased, and the deformation resistance of the slide rail device is increased, thereby improving the load capacity of the slide rail device.

### BRIEF DESCRIPTION OF THE DRAWINGS

Other features and advantages of the disclosure will become apparent in the following detailed description of the embodiments with reference to the accompanying drawings. It is noted that various features may not be drawn to scale.

FIG. 1 is a perspective view illustrating an embodiment of a multi-section slide rail device according to the disclosure.

FIG. 2 is an exploded perspective view of the embodiment.

FIG. 3 is a schematic side view of the embodiment.

FIG. 4 is a fragmentary perspective view of the embodiment, illustrating a state in which a middle rail section and an inner rail section are extended relative to an outer rail section.

FIG. 5 is a perspective view of a bracing member of the embodiment.

FIG. 6 is a perspective view illustrating another embodiment of the multi-section slide rail device according to the disclosure.

FIG. 7 is an exploded perspective view of the embodiment.

FIG. 8 is a schematic side view of the embodiment.

FIG. 9 is a fragmentary perspective view of the embodiment, illustrating a state in which a middle rail section and an inner rail section are extended relative to an outer rail section.

FIG. 10 is a perspective view of a bracing member of the embodiment in a modified form.

FIG. 11 is a side view of the bracing member.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

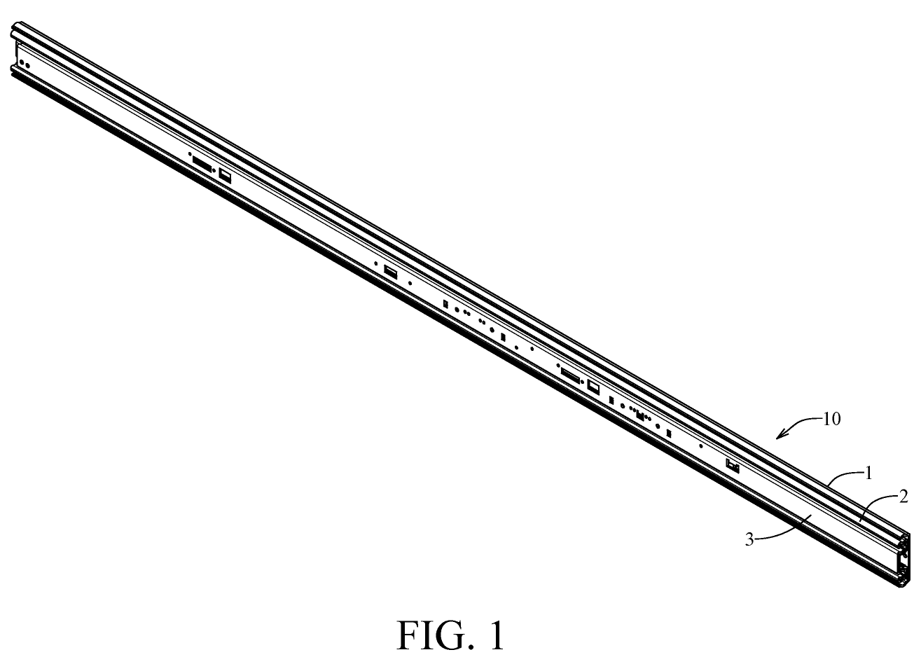

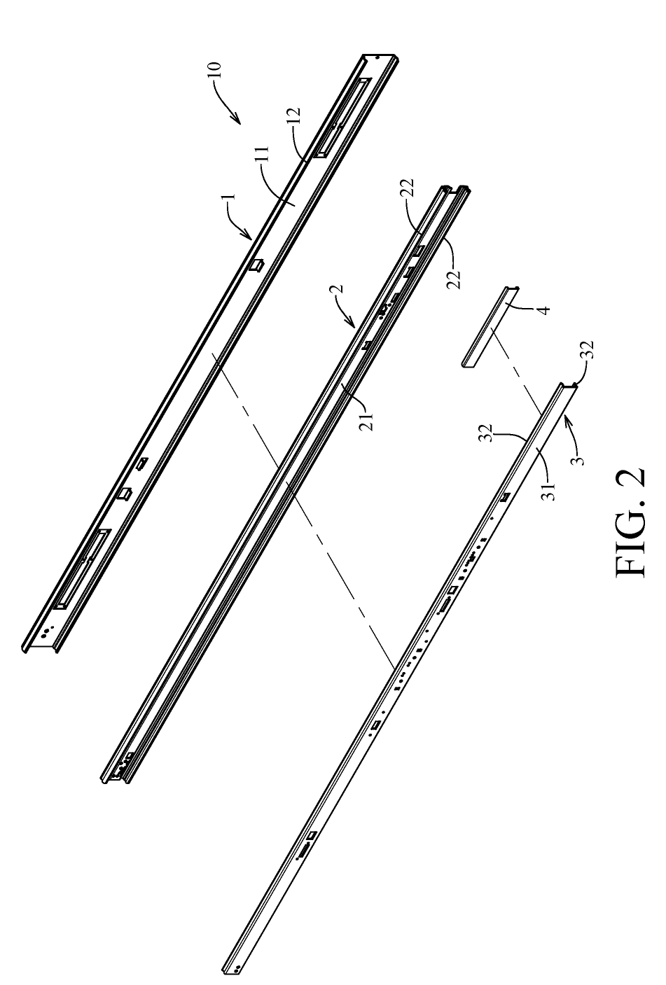

Referring to FIGS. 1 and 2, an embodiment of a multi-section slide rail device 10 according to the disclosure is adapted to be mounted on a server rack (not shown) for a server case (not shown) to be mounted thereon. The multi-section slide rail device 10 includes an outer rail section 1, a middle rail section 2, an inner rail section 3 and a bracing member 4.

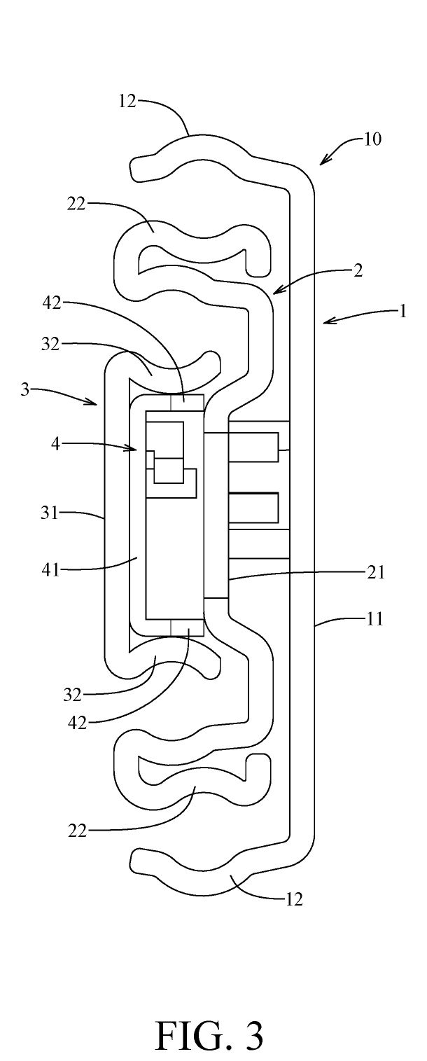

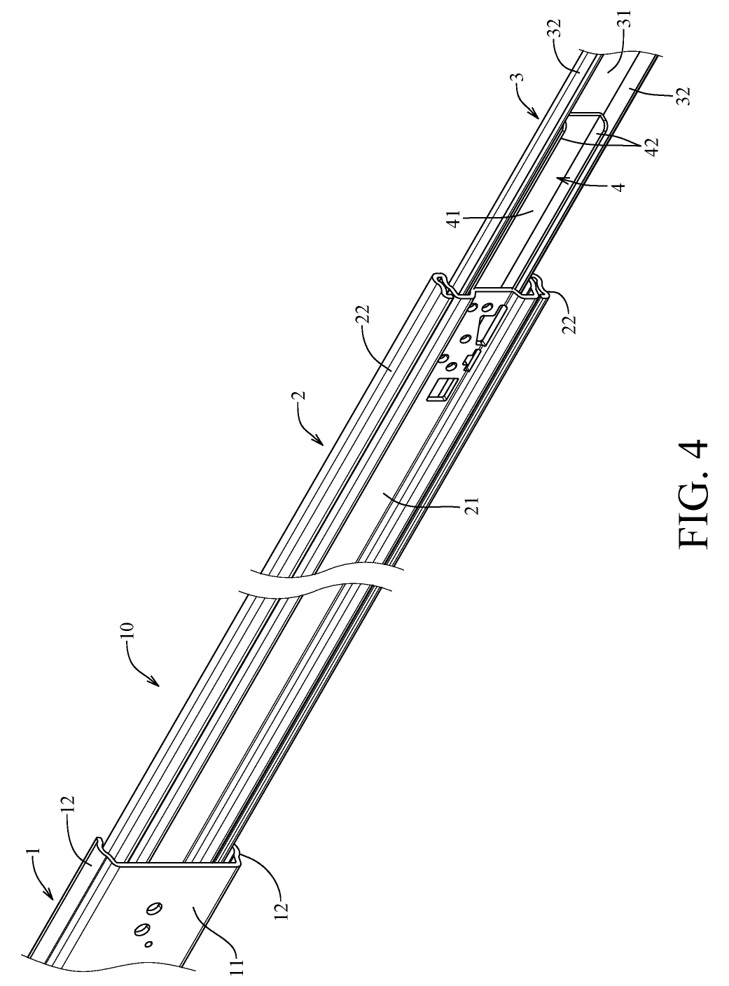

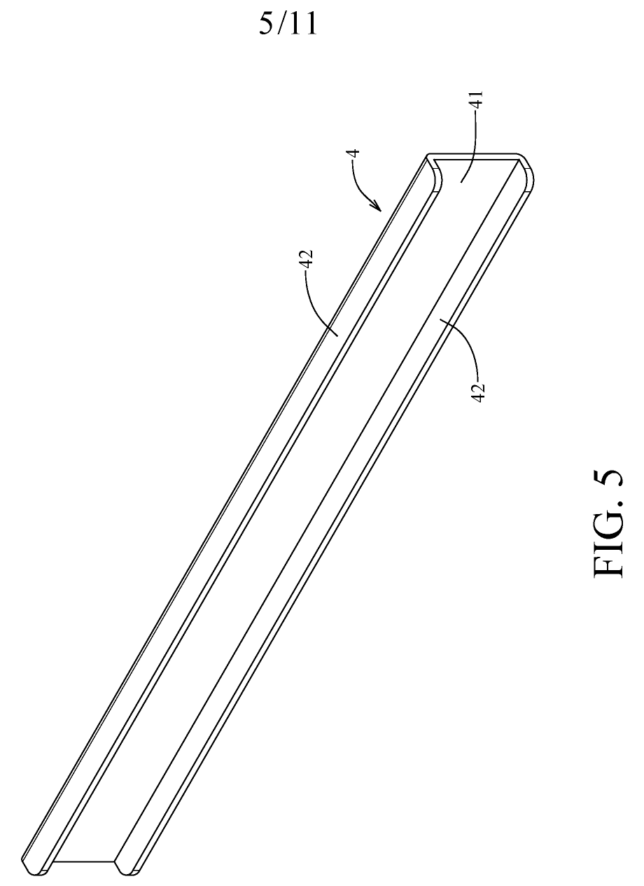

With reference to FIGS. 3 to 5, the outer rail section 1 has an outer upright wall 11 which extends in a lengthwise direction and has outer upper and lower side edges, and two outer lateral walls 12 which respectively extend from the outer upper and lower side edges in a transverse direction that is transverse to the lengthwise direction. The middle rail section 2 is disposed on and slidable relative to the outer rail section 1 along the lengthwise direction, and has a middle upright wall 21 which extends in the lengthwise direction and has middle upper and lower side edges, and two middle lateral walls 22 which respectively extend from the middle upper and lower side edges in the transverse direction. The inner rail section 3 is disposed on and slidable relative to the middle rail section 2 along the lengthwise direction for the server case (not shown) to be mounted thereon. The inner rail section 3 has an inner upright wall 31 which extends in the lengthwise direction and has inner upper and lower side edges, and two inner lateral walls 32 which respectively extend from the inner upper and lower side edges in the transverse direction. The bracing member 4 is securely disposed on the inner rail section 3 by means of screws or rivets, and is in abutting engagement with the inner lateral walls 32 in an upright direction that is transverse to both of the lengthwise direction and the transverse direction. The bracing member 4 includes an upright attached wall 41 which is securely disposed on the inner upright wall 31 and has bracing upper and lower side edges, and upper and lower abutting walls 42 which respectively extend from the bracing upper and lower side edges in the transverse direction and which are respectively in abutting engagement with the inner lateral walls 32. In the embodiment, the upright attached wall 41 is securely attached to the inner upright wall 31. Alternatively, the upright attached wall 41 may be spaced apart from the inner upright wall 31. In this embodiment, the bracing member 4 has a U-shaped cross-section. Alternatively, the bracing member 4 may have an I-shaped cross-section such that two ends of each abutting wall 42 project from the corresponding side edge of the upright attached wall 41.

The multi-section slide rail device 10 is shiftable between an initial state and an extended state. In the initial state, the outer rail section 1, the middle rail section 2 and the inner rail section 3 overlap one another. In the extended state, the middle rail section 2 is extended relative to the outer rail section 1, the inner rail section 3 is extended relative to the middle rail section 2, and the bracing member 4 is disposed at the junction of the middle rail section 2 and the inner rail section 3. With the bracing member 4 disposed on the inner upright wall 31 and in abutting engagement with the inner lateral walls 32, a torque generated by the server case (not shown) and applied to the middle rail section 2 and the inner rail section 3 is partly borne by the bracing member 4, the structural strength of the inner rail section 3 is increased, and the deformation resistance of the slide rail device 10 is increased, thereby improving the load capacity of the slide rail device 10.

In this embodiment, the middle rail section 2 serves as a first rail section, and the inner rail section 3 serves as a second rail section. In other embodiments, the first rail section may be the outer rail section 1, and the second rail section may be the middle rail section 2.

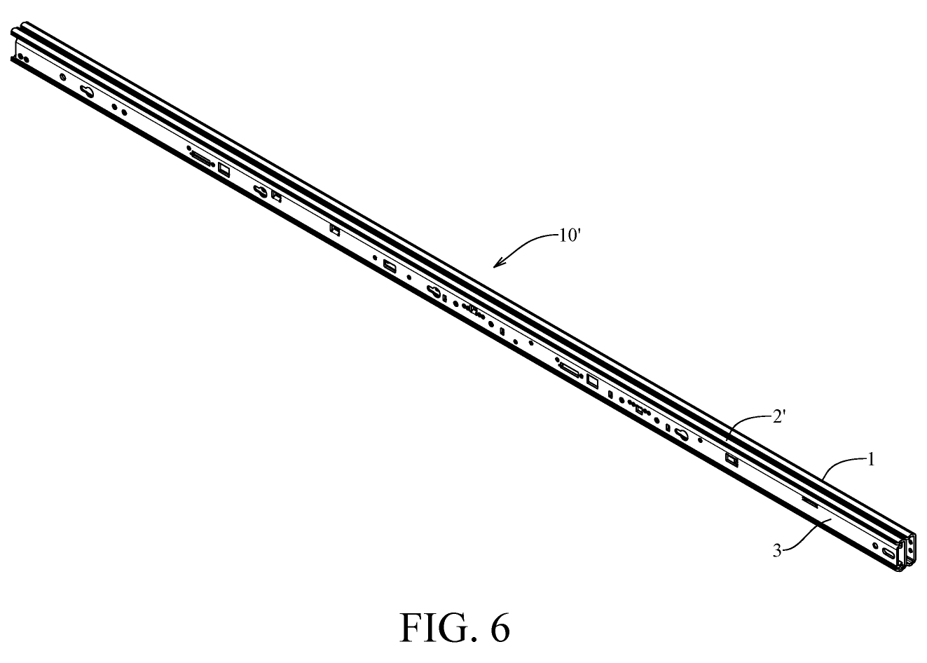

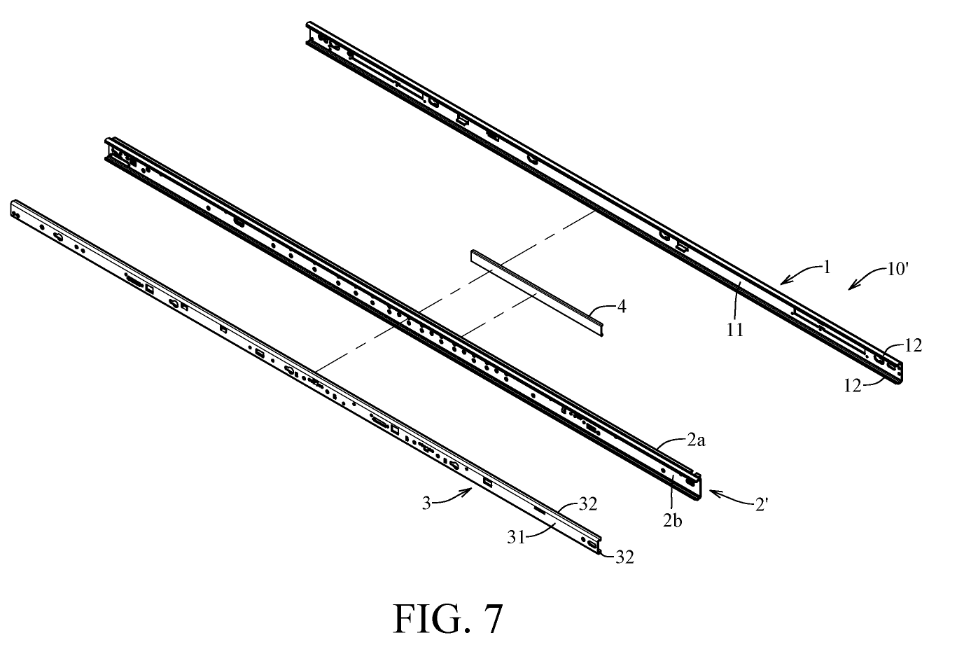

With reference to FIGS. 6 and 7, in another embodiment, the multi-section slide rail device 10’ adapted to be disposed on a server rack (not shown) for a server case (not shown) to be mounted thereon includes an outer rail section 1, a middle rail section 2’, an inner rail section 3 and a bracing member 4.

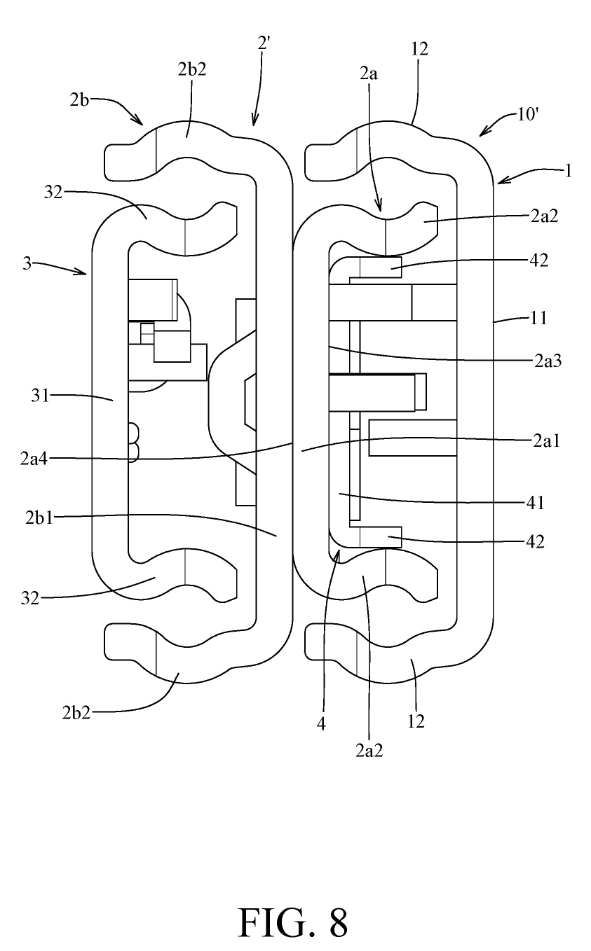

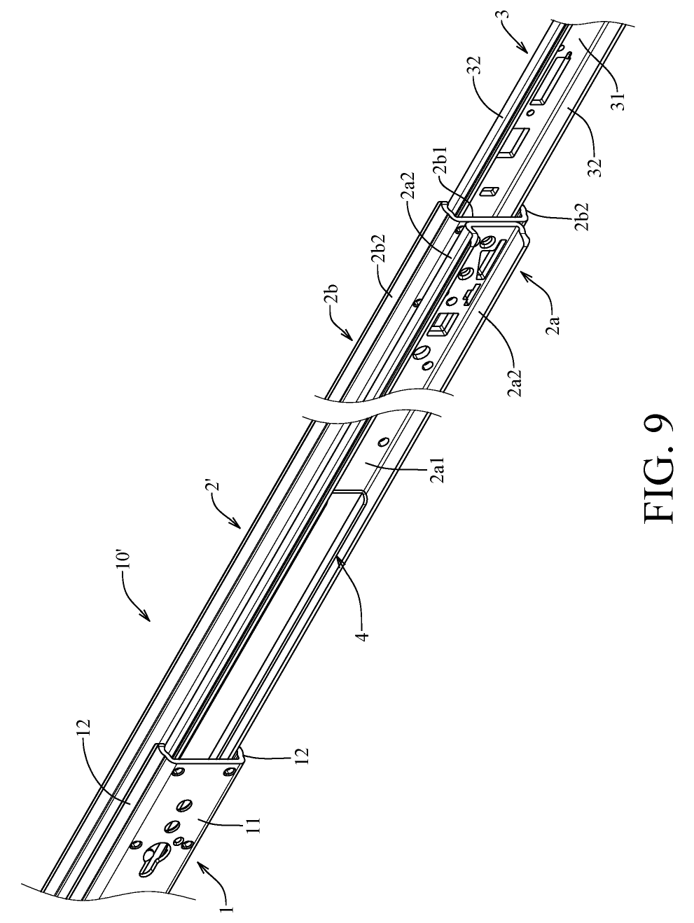

With reference to FIGS. 8 and 9, the outer rail section 1 has an outer upright wall 11 and two outer lateral walls 12 which respectively extend from outer upper and lower side edges in a transverse direction. The middle rail section 2’ is disposed on and slidable relative to the outer rail section 1 along a lengthwise direction, and includes a middle outer part 2a which is disposed on and slidable relative to the outer rail section 1 along the lengthwise direction, and a middle inner part 2b which is securely connected with the middle outer part 2a. The middle outer part 2a has a middle outer upright wall 2a1 which extends in the lengthwise direction and has middle upper and lower side edges, and two middle outer lateral walls 2a2 which respectively extend from the middle upper and lower side edges of the middle outer upright wall 2a1 in the transverse direction. The middle inner part 2b has a middle inner upright wall 2b1 which extends in the lengthwise direction and has middle upper and lower side edges, and two middle inner lateral walls 2b2 which respectively extend from the middle upper and lower side edges of the middle inner upright wall 2b1 in the transverse direction. The middle outer upright wall 2a1 of the middle outer part 2a has inner and outer surfaces 2a3, 2a4 which are opposite to each other in the transverse direction. The middle inner upright wall 2b1 of the middle inner part 2b is securely attached to the outer surface 2a4 of the middle outer upright wall 2a1. The middle outer lateral walls 2a2 of the middle outer part 2a extend from the inner surface 2a3 of the middle outer upright wall 2a1 toward the outer upright wall 11 of the outer rail section 1, and the middle inner lateral walls 2b2 of the middle inner part 2b extend from the middle inner upright wall 2b1 away from the outer upright wall 11 of the outer rail section 1. That is to say, the extending direction of the middle outer lateral walls 2a2 of the middle outer part 2a is opposite to that of the middle inner lateral walls 2b2 of the middle inner part 2b. The width of the middle inner upright wall 2b1 is greater than that of the middle outer upright wall 2a1. In the embodiment, the middle rail section 2’ is configured to have two rail parts connected with each other so as to have a higher structural strength. The inner rail section 3 is disposed on and slidable relative to the middle rail section 2’ along the lengthwise direction for the server case (not shown) to be mounted thereon. The inner rail section 3 has an inner upright wall 31 and two inner lateral walls 32 which respectively extend from inner upper and lower side edges of the inner upright wall 31 in the transverse direction. The bracing member 4 is securely disposed on and attached to the inner surface 2a3 of the second upright wall 2a1 of the middle rail section 2’ by means of screws or rivets, and has an upright attached wall 41 and upper and lower abutting walls 42. In the embodiment, the upright attached wall 41 is securely attached to the middle outer upright wall 2a1. Alternatively, the upright attached wall 41 may be spaced apart from the middle outer upright wall 2a1.

In this embodiment, the outer rail section 1 serves as a first rail section, and the middle rail section 2’ serves as a second rail section. The middle outer part 2a serves as a first part, and the middle inner part 2b serves as a second part such that the middle outer upright wall 2a1 and the middle inner upright wall 2b1 cooperatively serve as a second upright wall, and the middle outer lateral walls 2a2 and the middle inner lateral walls 2b2 cooperatively serve as second lateral walls.

The multi-section slide rail device 10’ is shiftable between an initial state and an extended state. In the initial state, the outer rail section 1, the middle rail section 2’ and the inner rail section 3 overlap one another. In the extended state, the middle rail section 2’ is extended relative to the outer rail section 1, the inner rail section 3 is extended relative to the middle rail section 2’, and the bracing member 4 is disposed at the junction of the outer rail section 1 and the middle rail section 2’. With the bracing member 4 disposed on the middle outer upright wall 2a1 of the middle rail section 2’ and in abutting engagement with the middle outer lateral walls 2a2, a torque generated by the server case (not shown) and applied to the middle rail section 2’ and the inner rail section 3 is partly borne by the bracing member 4, the structural strength of the middle rail section 2’ is increased, and the deformation resistance of the slide rail device 10’ is increased, thereby improving the load capacity of the slide rail device 10’.

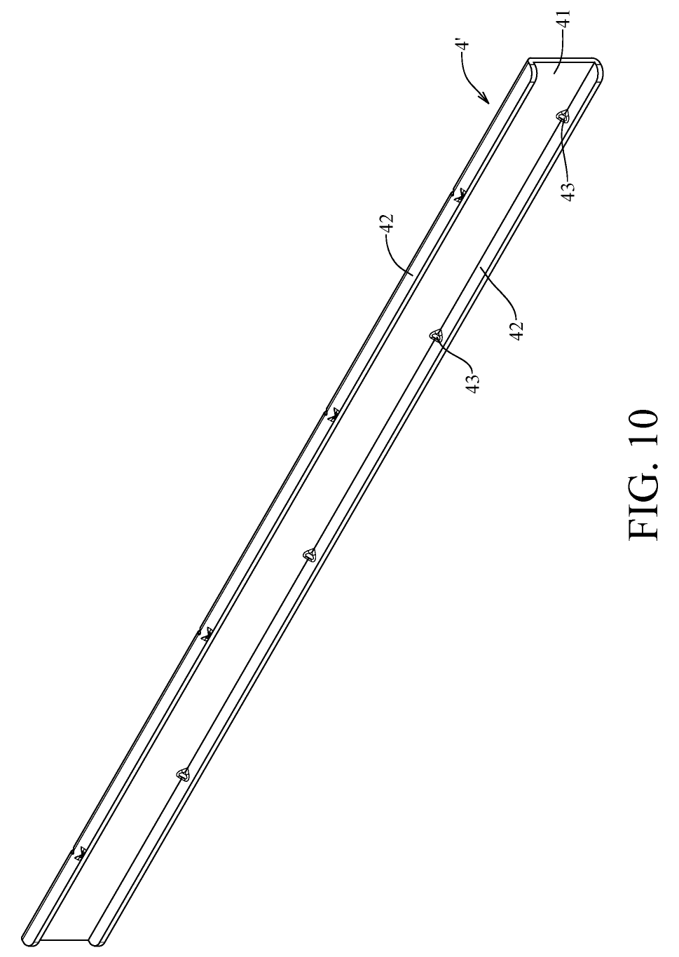

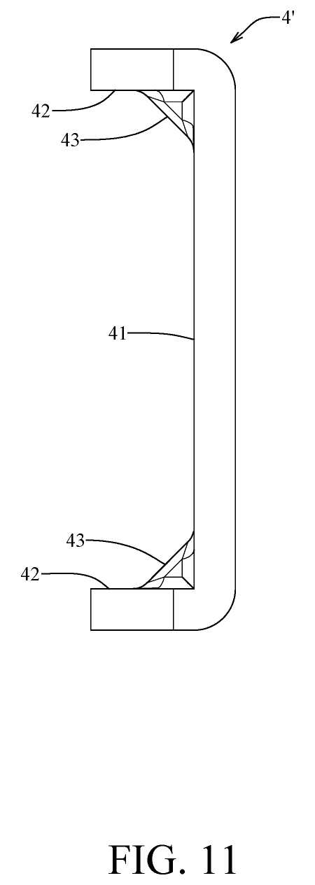

With reference to FIGS. 10 and 11, in other embodiments, the bracing member 4’ is provided in a modified form, and is securely disposed on the middle rail section 2’ by means of screws or rivets and in abutting engagement with the middle outer lateral walls 2a2 in the upright direction. The bracing member 4’ includes an upright attached wall 41 which is securely disposed on the middle outer upright wall 2a1, upper and lower abutting walls 42 which respectively extend from the bracing upper and lower side edges of the upright attached wall 41 in the transverse direction and which are respectively in abutting engagement with the middle outer lateral walls 2a2, and a plurality of reinforcing ribs 43 each of which being disposed between the upright attached wall 41 and one of the upper and lower abutting walls 42. The reinforcing ribs 43 are spaced apart from each other in both the lengthwise direction and the upright direction. Each reinforcing rib 43 may be in the form of a block. Alternatively, each reinforcing rib 43 may be in the form of a strip having two ends which are respectively connected with the upper and lower abutting walls 42.

As illustrated, with the bracing member 4, 4’ disposed on the second rail section 3, 2’ and in abutting engagement with the second lateral walls 32, 2a2, the structural strength of the second rail section 3, 2’ is increased, and the deformation resistance of the slide rail device 10, 10’ is increased, thereby improving the load capacity of the slide rail device 10, 10’.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A multi-section slide rail device, comprising:
a first rail section having a first upright wall which extends in a lengthwise direction and has a first upper side edge and a first lower side edge, and two first lateral walls which respectively extend from said first upper side edge and said first lower side edge in a transverse direction that is transverse to the lengthwise direction;
a second rail section disposed on and slidable relative to said first rail section along the lengthwise direction, and having a second upright wall which extends in the lengthwise direction and has a second upper side edge and a second lower side edge, and two second lateral walls which respectively extend from said second upper side edge and said second lower side edge in the transverse direction; and
a bracing member disposed on said second rail section and in abutting engagement with said second lateral walls in an upright direction that is transverse to both of the lengthwise direction and the transverse direction.

2. The multi-section slide rail device as claimed in claim 1, wherein said bracing member includes an upright attached wall which is securely disposed on said second upright wall and has a bracing upper side edge and a bracing lower side edge, and an upper abutting wall and a lower abutting wall which respectively extend from said bracing upper side edge and said bracing lower side edge in the transverse direction and which are respectively in abutting engagement with said second lateral walls.

3. The multi-section slide rail device as claimed in claim 2, wherein said bracing member further includes a plurality of reinforcing ribs each of which being disposed between said upright attached wall and one of said upper abutting wall and said lower abutting wall and spaced apart from each other in both of the lengthwise direction and the upright direction.

4. The multi-section slide rail device as claimed in claim 1, wherein said second rail section includes a first part which is disposed on and slidable along said first rail section, and a second part which is securely connected with said first part, each of said first and second parts having said second upright wall and said two second lateral walls, said second upright wall of said first part having an inner surface and an outer surface which are opposite to each other in the transverse direction, said bracing member being securely attached to said inner surface of said second upright wall, said second upright wall of said second part being securely attached to said outer surface of said second upright wall, said second lateral walls of said first part extending from said inner surface toward said first upright wall, said second lateral walls of said second part extending from said second upright wall away from said first upright wall.
